(19) United States
(12) Patent Application Publication
(10) Pub. No.: US 2025/0366282 A1
(43) Pub. Date: Nov. 27, 2025

(54) LIGHT EMITTING DEVICE PRODUCING METHOD AND BLACK TRANSFER FILM

(71) Applicant: DEXERIALS CORPORATION, Shimotsuke-shi, Tochigi (JP)

(72) Inventors: Reiji TSUKAO, Shimotsuke-shi (JP); Naoki HAYASHI, Shimotsuke-shi (JP); Daiki NODA, Shimotsuke-shi (JP); Kazumu WATANABE, Shimotsuke-shi (JP); Toshiki SHIRAIWA, Shimotsuke-shi (JP)

(73) Assignee: DEXERIALS CORPORATION, Shimotsuke-shi, Tochigi (JP)

(21) Appl. No.: 18/873,844

(22) PCT Filed: Apr. 26, 2023
(86) PCT No.: PCT/JP2023/016379

§ 371 Date: Dec. 11, 2024

(30) Foreign Application Priority Data
Jul. 28, 2022 (JP) 2022-120533

(51) Int. Cl. H10H 29/03; H10H 29/855

(52) U.S. Cl. CPC H10H 29/03; H10H 29/8552

(57) ABSTRACT

A producing method for a light-emitting device including a black matrix in at least a part of peripheries of light-emitting elements on a wiring substrate includes: a step of allowing a black transfer film with a black transfer layer formed on one side of a light-transmitting base material to face, from the black transfer layer side, the substrate before the light-emitting elements are disposed; a step of applying laser light to the black transfer film from the base material side, transferring pieces of the black transfer layer to positions on the substrate of the light-emitting elements; and a step of disposing and mounting the light-emitting elements on the pieces of the black transfer layer that have been transferred to the substrate, deforming the black transfer layer to form a black matrix in at least a part of the peripheries of the light-emitting elements and connecting the elements to the substrate.

### TECHNICAL FIELD

The present invention relates to a producing method for a light-emitting device such as an image display device or a lighting device that uses a light-emitting element such as a micro LED (Light Emitting Diode), and to a black transfer film used in the producing method.

### BACKGROUND ART

In recent years, micro LED displays, which emit light directly from micro LEDs with high luminous efficiency and long life, have been expected to offer desirable characteristics such as high luminance, low power consumption, high contrast, and long life. In such micro LED displays, red LEDs, green LEDs, and blue LEDs are provided at specified intervals on a display substrate. Furthermore, these LEDs spontaneously emit light. Thus, there are cases in which a color filter separated by a black matrix for each color is not used. In such cases, it is necessary to form a black matrix between the micro LEDs to prevent color mixing (PTLs 1 and 2).

Examples of known methods for forming a black matrix in micro LED displays include: (a) a method in which a black transfer layer forming composition is applied to the entire surface of one side of a display substrate before micro LEDs are mounted thereon, and the black transfer layer forming composition applied to a non-black matrix region of the display substrate is removed by an etching process or a photolithography process; (b) a method in which a black transfer film in which a black matrix has been formed on a carrier film by screen printing is aligned and attached to a display substrate before micro LEDs are mounted thereon, and then the carrier film is peeled off; (c) a method in which a display substrate, on which micro LEDs have been mounted, is covered with a cover glass on which a black matrix is formed; and (d) a method in which a black matrix ink composition is applied with an inkjet method between micro LEDs of a display substrate on which the micro LEDs have been mounted.

### CITATION LIST

### Patent Literature

PTL 1: Japanese Translation of PCT Patent Application Publication No. 2021-506108

PTL 2: WO2021/060832A1

### SUMMARY OF INVENTION

### Technical Problem

However, in the above-mentioned method (a), forming the black matrix is time-consuming. The above-mentioned methods (b) and (c) do not provide sufficient positional accuracy for the black matrix. In the above-mentioned method (d), it is difficult to form a black matrix with a sufficient height to suppress color mixing of the micro LEDs. Additionally, it is necessary for these methods to achieve sufficient alignment accuracy for mounting the micro-LEDs.

An object of the present invention is to produce a light-emitting device such as an image display device or a lighting device using micro LEDs
while ensuring formation of a black matrix without requirement of much time, ensuring sufficient positional accuracy of the black matrix, enabling the formation of the black matrix with a height sufficient to suppress color mixing of the micro LEDs, and ensuring sufficient alignment accuracy for mounting the micro LEDs.

### Solution to Problem

The present inventors have found that the above-mentioned object can be achieved by using a laser lift-off method, which is known as one of the production techniques for semiconductor devices, and thus completed the present invention.

### (First Aspect)

That is, a first aspect of the present invention is a producing method for a light-emitting device including a black matrix in at least a part of the peripheries of light-emitting elements disposed on a wiring substrate, the producing method including the following step a, step b, and step c.

### (Step a)

A step of allowing a black transfer film with a black transfer layer that has been formed on one side of a light-transmitting base material to face, from the black transfer layer side, the wiring substrate before the light-emitting elements are disposed thereon.

### (Step b)

Next, a step of applying laser light to the black transfer film from the light-transmitting base material side thereof, thereby transferring individual pieces of the black transfer layer to positions on the wiring substrate where the light-emitting elements are to be disposed.

### (Step c)

A step of disposing and mounting the light-emitting elements on the individual pieces of the black transfer layer that have been transferred to the wiring substrate, thereby deforming the black transfer layer to form a black matrix in at least the part of the peripheries of the light-emitting elements and connecting the light-emitting elements to the wiring substrate.

### (Second Aspect)

Furthermore, a second aspect of the present invention is a producing method for a light-emitting device including a black matrix in at least a part of the peripheries of light-emitting elements disposed on a wiring substrate, the producing method including the following step Ala and step Alb.

### (Step A1a)

A step of allowing a black transfer film with a black transfer layer that has been formed on one side of a light-transmitting base material to face, from the black transfer layer side, the wiring substrate on which the light-emitting elements have been disposed.

### (Step A1b)

Next, a step of applying laser light to the black transfer film from the light-transmitting base material side thereof, thereby transferring individual pieces of the black transfer layer to at least the part of the peripheries of the light-emitting elements on the wiring substrate to form a black matrix.

### (Third Aspect)

Furthermore, a third aspect of the present invention is a producing method for a light emitting device including a black matrix in at least a part of the peripheries of light-emitting elements disposed on a wiring substrate, the producing method including the following step A2a, step A2b, and step B.

### (Step A2a)

A step of allowing a black transfer film with a black transfer layer that has been formed on one side of a light-transmitting base material to face, from the black transfer layer side, the wiring substrate before the light-emitting elements are disposed thereon.

### (Step A2b)

Next, a step of applying laser light to the black transfer film from the light-transmitting base material side thereof, thereby transferring individual pieces of the black transfer layer to at least a part of the peripheries of positions of the wiring substrate where the light-emitting elements are to be disposed to form a black matrix.

### (Step B)

A step of disposing the light-emitting elements between the black matrices that have been transferred to the wiring substrate.

In the above-mentioned first to third aspects of the present invention, the light-emitting elements are preferably micro LEDs. The black transfer film to be used may be a film in which the black transfer layer is provided as a full-surface-applied layer on one side of the light-transmitting base material. However, the black transfer film is preferably a film in which individual pieces of the black transfer layer are provided on the light-transmitting base material so as to correspond to at least a part of the peripheries, preferably the entire peripheries, of positions of the wiring substrate where the light-emitting elements are to be disposed. Furthermore, the black transfer layer of the black transfer film can include conductive particles. Inclusion of conductive particles makes it possible to provide the black transfer layer with conductivity or anisotropic conductivity.

(Fourth aspect)

A fourth aspect of the present invention is a black transfer film for forming a black matrix by using a laser lift-off method, the black transfer film being used in the first to third aspects of the present invention.

More specifically, the fourth aspect of the present invention is a black transfer film including a light-transmitting base material and a black transfer layer formed on one side of the light-transmitting base material. This black transfer layer includes a black pigment and a thermosetting composition, and has a visible light transmittance according to JIS K 7375 of less than 20% and a tack force according to JIS Z 0237 of 0.1 MPa or more. In this black transfer film, the black transfer layer may be provided on the light-transmitting base material as a full-surface-applied layer. However, the black transfer layer is preferably provided on the light-transmitting base material in the form of individual pieces corresponding to a black matrix to be formed. Furthermore, the black transfer layer of the black transfer film may include conductive particles as described above, and the black transfer layer including the conductive particles can exhibit conductivity or anisotropic conductivity. Such a black transfer layer can be preferably used to obtain electrical conduction between electrodes, thus simultaneously achieving the formation of the black matrix and the connection of the light-emitting elements. This makes it possible to simplify the production process and reduce production costs.

### Advantageous Effects of Invention

In the method for producing the light-emitting device such as an image display device or a lighting device of the present invention, the so-called laser lift-off method is used, so that it does not take much time to form the black matrix, the positional accuracy of the black matrix can be sufficiently ensured, the black matrix can be formed with a height sufficient to suppress color mixing of the micro LEDs, and the alignment accuracy for mounting the micro LEDs can be sufficiently ensured.

### BRIEF DESCRIPTION OF DRAWINGS

FIG. 1A is a process diagram for describing a first aspect of the present invention.

FIG. 1B is a process diagram for describing the first aspect of the present invention.

FIG. 1C is a process diagram for describing the first aspect of the present invention.

FIG. 1D is a process diagram for describing the first aspect of the present invention.

FIG. 1E is a process diagram for describing the first aspect of the present invention.

FIG. 2A is a process diagram for describing a second aspect of the present invention.

FIG. 2B is a process diagram for describing the second aspect of the present invention.

FIG. 2C is a process diagram for describing the second aspect of the present invention.

FIG. 3A is a process diagram for describing a third aspect of the present invention.

FIG. 3B is a process diagram for describing the third aspect of the present invention.

FIG. 3C is a process diagram for describing the third aspect of the present invention.

FIG. 3D is a process diagram for describing the third aspect of the present invention.

FIG. 3E is a process diagram for describing the third aspect of the present invention.

### DESCRIPTION OF EMBODIMENTS

Hereinafter, the present invention will be described in detail with reference to the drawings. In the drawings, the same reference numerals denote the same or equivalent constituent elements.

### <First Aspect of Present Invention>

A first aspect of the present invention is a method for producing a light emitting device such as an image display device or a lighting device including a black matrix in at least a part of the peripheries of light-emitting elements disposed on a wiring substrate, the method including the following step a, step b, and step c.

### (Step a)

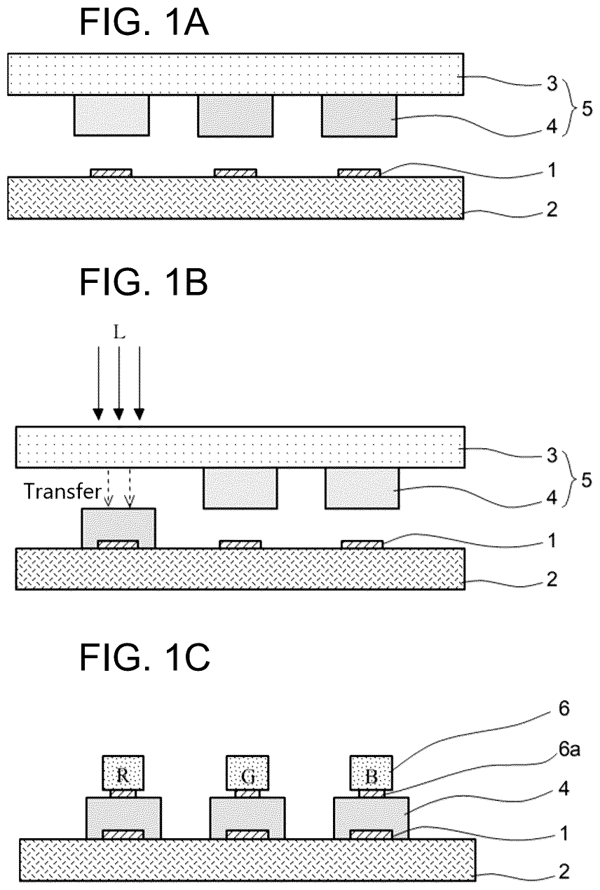

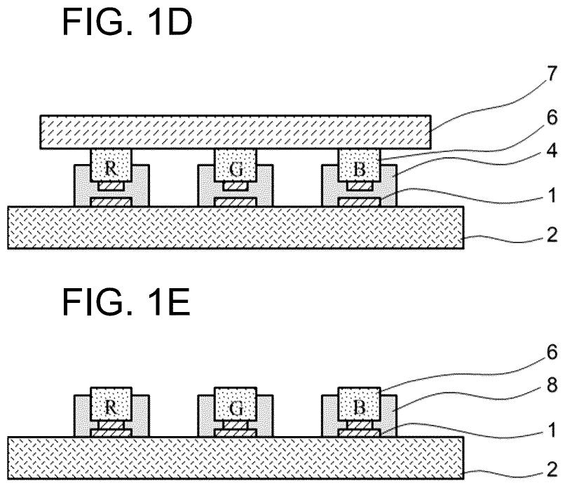

A step a is a step of allowing a black transfer layer to face a wiring substrate in order to transfer individual pieces of the black transfer layer to the wiring substrate. Specifically, as shown in FIG. 1A, the step a is a step of allowing a black transfer film 5 having a black transfer layer 4 that has been formed on one side of a light-transmitting base material 3 to face, from the black transfer layer 4 side, a wiring substrate 2 having a wiring 1 that has been formed thereon before light-emitting elements are disposed on the wiring substrate 2. Note that, in FIG. 1A, the black transfer layer 4 is formed in the form of individual pieces on one side of the light-transmitting base material 3. However, the black transfer layer 4 may be formed as a full-surface-applied layer on one side of the light-transmitting base material 3. As a method for providing the black transfer layer 4 in the form of individual pieces on one side of the light-transmitting base material 3, a known method such as a screen printing method, an etching method, or an inkjet method can be adopted.

### (Step b)

Next, as shown in FIG. 1B, a laser lift-off method is used to apply laser light L to the black transfer film 5 from the light-transmitting base material 3 side thereof, thereby transferring the individual pieces of the black transfer layer 4 to positions of the wiring substrate 2 where the light-emitting elements are to be disposed (i.e., positions covering the wiring 1). As a laser lift-off device for performing the laser lift-off method, a laser lift-off device (MT-30C200) can be used. Note that, even when the black transfer layer 4 is provided as a full-surface-applied layer on the light-transmitting base material 3, the black transfer layer can be transferred in the form of individual pieces by the laser lift-off method.

### (Step c)

A step c is a step of forming a black matrix and mounting the light-emitting elements by a thermocompression bonding process, a reflow process, or the like. Specifically, as shown in FIG. 1C, light-emitting elements 6 (R, G, B) are placed, from the electrodes 6a side, on the individual pieces of the black transfer layer 4 that has been transferred to the wiring substrate 2, and as shown in FIG. 1D, the black transfer layer 4 is deformed by thermocompression bonding using a bonding tool 7 or the like. As a result, as shown in FIG. 1E, a black matrix 8, which is a resulting product of the deformed black transfer layer 4 by the thermos-curing, is formed in at least a part of the peripheries, preferably the entire peripheries, of the light-emitting elements 6, and the light-emitting elements 6 are connected to the wiring substrate 2, thereby obtaining a light-emitting device such as an image display device or a lighting device. When disposing the light-emitting elements 6, as necessary, the light-emitting elements 6 can be disposed via a layer formed from an adhesive film, a conductive adhesive film or anisotropic conductive adhesive film including conductive particles, or a layer formed from a metal with a low-melting point such as solder (e.g., solder paste), or the like. This layer is preferably an adhesive layer including conductive particles.

### <Second Aspect of Present Invention>

A second aspect of the present invention is a method for producing a light emitting device such as an image display device or a lighting device including a black matrix in at least a part of the peripheries of light-emitting elements disposed on a wiring substrate, the method including the following step Ala and step Alb. In this second aspect, the black matrix is transferred to the wiring substrate, on which the light-emitting elements have been disposed, by using the laser lift-off method.

### (Step A1a)

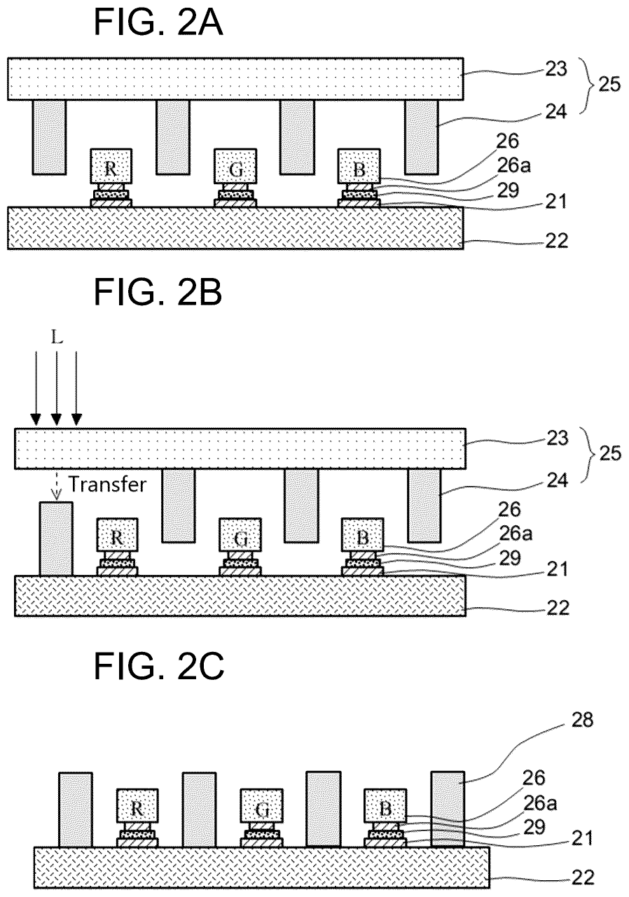

As shown in FIG. 2A, a step A1a is a step of allowing a black transfer film 25 having a black transfer layer 24 that has been formed on one side of a light-transmitting base material 23 to face, from the black transfer layer 24 side, a wiring substrate 22 having a wiring 21 that has been formed thereon, with light-emitting elements 26 (R, G, B) being disposed on the wiring substrate 22 from the electrodes 26a side. When disposing the light-emitting elements 26, as necessary, the light-emitting elements 26 can be disposed via a layer formed from an adhesive film, a conductive adhesive film or anisotropic conductive adhesive film including conductive particles, or a layer formed from a metal with a low-melting point such as solder (e.g., solder paste), or the like. This layer is preferably a conductive adhesive layer 29 including conductive particles.

### (Step A1b)

Next, as shown in FIG. 2B, laser light L is applied to the black transfer film 25 from the light-transmitting base material 23 side thereof by using a laser lift-off method, thereby transferring individual pieces of the black transfer layer 24 to at least the part of the peripheries of the light-emitting elements 26 of the wiring substrate 22. Then, the individual pieces are thermally cured as necessary to form a black matrix 28. As shown in FIG. 2C, this makes it possible to obtain a light emitting device such as an image display device or a lighting device in which a cured black matrix 28 is formed in at least a part of the peripheries, preferably the entire peripheries, of the light-emitting elements 26.

### <Third Aspect of Present Invention>

A third aspect of the present invention is a method for producing a light emitting device such as an image display device or a lighting device including a black matrix in at least a part of the peripheries of light-emitting elements disposed on a wiring substrate, the method including the following step A2a, step A2b, and step B.

### (Step A2a)

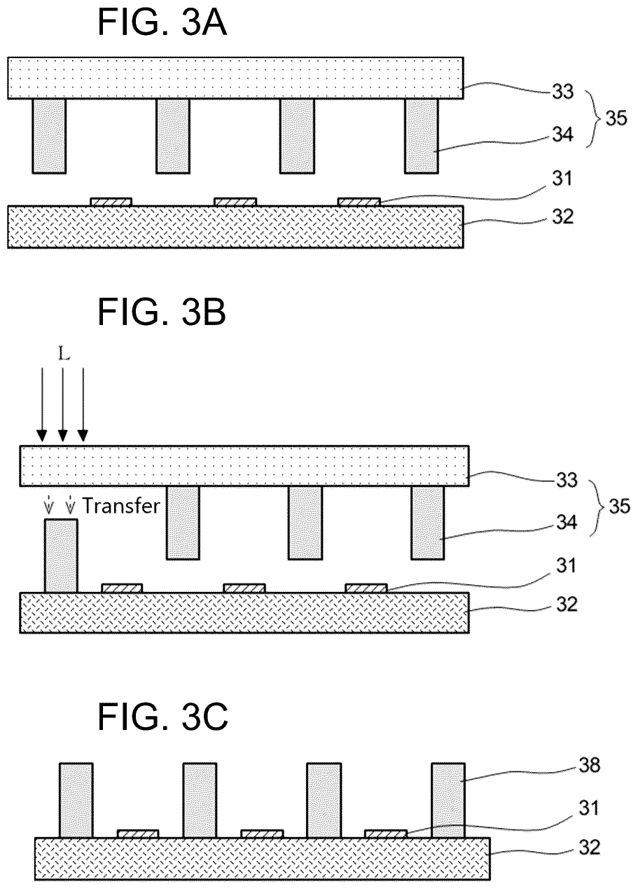

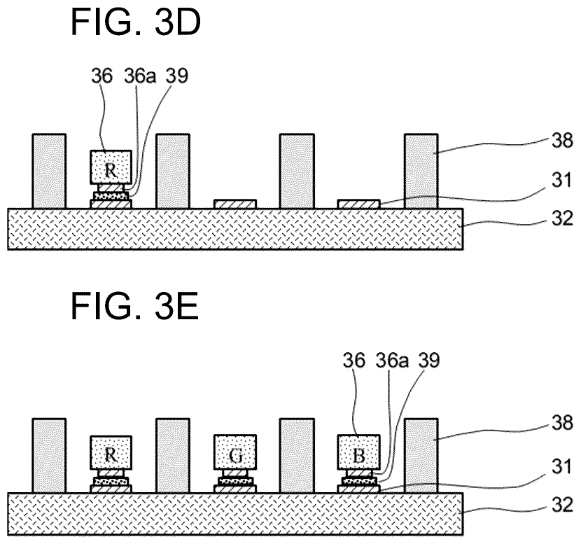

As shown in FIG. 3A, a step A2 is a step of allowing a black transfer film 35 having a black transfer layer 34 that has been formed on one side of a light-transmitting base material 33 to face, from the black transfer layer 34 side, a wiring substrate 32 having a wiring 31 that has been formed thereon before the light-emitting elements are disposed on the wiring substrate 32.

### (Step A2b)

Next, as shown in FIG. 3B, laser light L is applied to the black transfer film 35 from the light-transmitting base material 33 side thereof by using the laser lift-off method, so that, as shown in FIG. 3C, individual pieces of the black transfer layer 34 are transferred to at least a part of the peripheries, preferably the entire peripheries, of positions of the wiring substrate 32 where the light-emitting elements are to be disposed. Then, the individual pieces are thermally cured as necessary to form a black matrix 38.

### (Step B)

A step B is a step of mounting the light-emitting elements, and specifically, as shown in FIG. 3D, the step B is a step of disposing light-emitting elements 36, from the electrodes 36a side, between the black matrices 38 that have been transferred to the wiring substrate 32 on which no light-emitting elements are disposed, using a known method. As shown in FIG. 3E, this makes it possible to obtain a light emitting device such as an image display device or a lighting device in which the black matrices 38 are formed in at least a part of the peripheries, preferably the entire peripheries, of the light-emitting elements 36. When disposing the light-emitting elements 36, as necessary, the light-emitting elements 36 can be disposed via a layer formed from an adhesive film, a conductive adhesive film or anisotropic conductive adhesive film including conductive particles, or a layer formed from a metal with a low-melting point such as solder (e.g., solder paste), or the like. This layer is preferably a conductive adhesive layer 39 including conductive particles.

### (Light-Emitting Element)

In the above-mentioned first to third aspects of the present invention, the light-emitting elements are not particularly limited. However, the light-emitting elements are preferably micro LEDs. The size of the micro LED is preferably such that the maximum length in a plan view is 3 to 100 μm.

### (Black Transfer Film)

The black transfer film to be used may be a film in which the black transfer layer is provided as a full-surface-applied layer on one side of the light-transmitting base material (not illustrated). However, a black transfer film in which a black transfer layer is provided on a light-transmitting base material as individual pieces can be preferably used (refer to FIGS. 1A, 2A, and 3A). By handling the black transfer layer as individual pieces, the black transfer layer can be easily provided at designated sites of the substrate, and thus, productivity can be improved. In this case, the individual pieces of the black transfer layer are provided on the light-transmitting base material so as to correspond to at least a part of the peripheries, preferably the entire peripheries, of positions of the wiring substrate where the light-emitting elements are to be disposed. In the black transfer film having such a structure, the black transfer layer can be formed with a thickness sufficient to prevent color mixing of the micro LEDs.

The thickness of the light-transmitting base material constituting the black transfer film is preferably 0.5 μm or more and 10 μm or less, and more preferably 1 μm or more and 5 μm or less, from the viewpoint of the handling properties of the black transfer film. The lower limit of the thickness of the black transfer layer may be the same as the particle diameter of the conductive particles, and is preferably 1.3 times or more the conductive particle diameter or 3 μm or more. The upper limit is preferably not more than two times the conductive particle diameter or 20 μm or less. The black transfer film may be laminated with an adhesive layer or a pressure-sensitive adhesive layer containing no conductive particles, and the number of layers and the laminated surface thereof can be appropriately selected in accordance with its objects and purposes. As the insulating resin of the adhesive layer or the pressure-sensitive adhesive layer, the same resin as those of the thermosetting composition of the black transfer layer can be used. The film thickness can be measured using a known micrometer or digital thickness gauge. The film thickness may be determined by measuring, for example, 10 or more positions and averaging them.

### (Black Transfer Layer)

The black transfer layer of the black transfer film is transferred to another substrate or the like by a laser lift-off method, and, as necessary, is heat-cured to constitute a black matrix. The black transfer layer is blackened by containing, preferably, 5 to 30 parts by mass of a black pigment such as carbon black or titanium black relative to 100 parts by mass of the insulating thermosetting composition. Among these, titanium black, which has an extremely low content of impurity ions and is inherently insulating, can be preferably used. The average particle diameter of the black pigment is in a range of 10 to 100 nm. The average particle diameter of the black pigment is preferably smaller than the average particle diameter of the conductive particles.

The black transfer layer preferably exhibits excellent cushioning properties (impact absorbing properties) for stable adhesion to a substrate. As a result, it is possible to suppress the occurrence of defects such as misalignment, deformation, breakage, and omission of chip components, and to improve the transfer rate of the chip components by irradiation of the laser light. Such cushioning properties can be evaluated by durometer A hardness and/or storage elastic modulus, as described below.

The durometer A hardness of the black transfer layer is preferably 20 or more and 40 or less, more preferably 20 or more and 35 or less, and particularly preferably 20 or more and 30 or less. If the durometer A hardness is too high, the black transfer layer becomes too hard, so that defects such as deformation and breakage of chip components tend to occur easily. If the durometer A hardness is too low, the black transfer layer becomes too soft, and defects such as misalignment of chip components tend to occur easily. The durometer A hardness of the black transfer layer can be measured by using a durometer A in accordance with JIS K6253 with the rubber hardness (Japanese Industrial Standard JIS-A hardness).

The storage elastic modulus of the black transfer layer is preferably 60 MPa or less, more preferably 30 MPa or less, and particularly preferably 10 MPa or less. If the storage elastic modulus is too high, the impact of the chip component that has been ejected at high speed by laser irradiation cannot be absorbed, and the transfer rate of the chip component tends to decrease. The storage elastic modulus can be determined by dynamic viscoelasticity testing using a push-in tester (measuring at a temperature of 30° C. and a frequency of 200 Hz, using a flat punch with a diameter of 100 μm, setting a target push-in depth to 1 μm, and sweeping in a frequency range of from 1 to 200 Hz).

In addition, for the black matrix formed by the thermo-curing of the black transfer layer, the storage elastic modulus (30° C.) measured in a tensile mode in accordance with JIS K7244 is preferably 100 MPa or more, more preferably 2,000 MPa or more. If the storage elastic modulus at a temperature of 30° C. is too low, favorable conductivity is not achieved, and the connection reliability also tends to decrease. The storage elastic modulus at 30° C. can be measured in accordance with JIS K7244 in a tensile mode using a viscoelastic tester (Rheovibron), for example, at a frequency of 11 Hz and a temperature increase rate of 3° C./min.

The thermosetting composition constituting the black transfer layer preferably contains a rubber component, a film-forming resin, a thermosetting resin, a thermosetting agent, and an inorganic filler. As necessary, other known additives may be contained in a range in which the advantageous effects of the invention are not impaired.

### (Rubber Component)

The rubber component contained in the thermosetting composition is a component for realizing the cushioning properties (impact absorbing properties) of the black transfer layer and is not particularly limited as long as it is an elastomer having favorable cushioning properties. Specific examples thereof include an acrylic rubber, a silicone rubber, a butadiene rubber, and a polyurethane resin (a polyurethane-based elastomer). Among these, one or more types selected from an acrylic rubber and a silicone rubber are preferable. The content of the rubber component is preferably 1 part by mass or more and 20 parts by mass or less, and more preferably 2 parts by mass or more and 10 parts by mass or less, relative to 100 parts by mass of the total of the rubber component, the film-forming resin, the thermosetting resin, the thermosetting agent, and the inorganic filler.

### (Film-Forming Resin)

As the film-forming resin, various resins may be mentioned, preferably having a weight-average molecular weight of about 10,000 or more and 80,000 or less, such as a phenoxy resin, a polyester resin, a polyurethane resin, a polyester urethane resin, an acrylic resin, a polyimide resin, and a butyral resin, in terms of film-forming properties. These film-forming resins may be used alone or in combination of two or more. Among these, a phenoxy resin is preferably used from the viewpoint of film formation state, connection reliability, and the like. The content of the film-forming resin is preferably 20 parts by mass or more and 50 parts by mass or less, more preferably 25 parts by mass or more and 45 parts by mass or less, and particularly preferably 35 parts by mass or more and 45 parts by mass or less, relative to 100 parts by mass of the total of the rubber component, the film-forming resin, the thermosetting resin, the thermosetting agent, and the inorganic filler.

### (Thermosetting Resin)

Examples of the thermosetting resin include an epoxy compound and a (meth)acrylate compound. An epoxy compound is particularly preferable. These compounds may be a monomer, an oligomer, or a polymer. The content of the thermosetting resin is preferably 10 parts by mass or more and 50 parts by mass or less, more preferably 20 parts by mass or more and 40 parts by mass or less, and particularly preferably 25 parts by mass or more and 35 parts by mass or less, relative to 100 parts by mass of the total of the rubber component, the film-forming resin, the thermosetting resin, the thermosetting agent, and the inorganic filler.

The epoxy compound that can be used as the thermosetting resin is not particularly limited as long as it is an epoxy compound having one or more epoxy groups within the molecule, and may be, for example, a bisphenol A type epoxy resin, a bisphenol F type epoxy resin, or the like, or may be a urethane-modified epoxy resin. Among these, a high-purity bisphenol A type epoxy resin can be preferably used. Specific examples of the high-purity bisphenol A type epoxy resin include “YL980” (trade name) manufactured by Mitsubishi Chemical Corporation. When an epoxy compound is used as the thermosetting resin, the content of the epoxy compound is preferably 30 parts by mass or more and 60 parts by mass or less, more preferably 35 parts by mass or more and 55 parts by mass or less, and particularly preferably 35 parts by mass or more and 45 parts by mass or less, relative to 100 parts by mass of the total of the rubber component, the film-forming resin, the thermosetting resin, the thermosetting agent, and the inorganic filler.

### (Thermosetting Agent)

The thermosetting agent is selected according to the thermosetting resin. For example, when the thermosetting resin is an epoxy compound, a thermo-anionic polymerization initiator or a thermo-cationic polymerization initiator can be preferably selected, and a thermo-cationic polymerization initiator that is capable of suppressing the curing reaction by laser light and of rapidly curing by heat can be more preferably selected. The content of the thermosetting agent can be determined according to the type of the thermosetting agent, the type of the thermosetting resin, and the like. The content of the thermosetting agent is preferably 1 part by mass or more and 10 parts by mass or less, more preferably 2 parts by mass or more and 8 parts by mass or less, and particularly preferably 3 parts by mass or more and 6 parts by mass or less, relative to 100 parts by mass of the total of the rubber component, the film-forming resin, the thermosetting resin, the thermosetting agent, and the inorganic filler.

The thermo-cationic polymerization initiator which is preferably applicable to the epoxy compound is one that generates an acid capable of cationically polymerizing the cationic polymerization type compound by heat. Known iodonium salts, sulfonium salts, phosphonium salts, ferrocenes, or the like can be used. Among these, aromatic sulfonium salts exhibiting favorable latency with respect to temperature can be preferably used. Specific examples of the aromatic sulfonium salt-based polymerization initiator include “San Aid SI-60L” (trade name) manufactured by Sanshin Chemical Industry Co., Ltd. The content of the thermo-cationic polymerization initiator is preferably 1 part by mass or more and 15 parts by mass or less, more preferably 1 part by mass or more and 10 parts by mass or less, and particularly preferably 3 parts by mass or more and 8 parts by mass or less, relative to 100 parts by mass of the total of the rubber component, the film-forming resin, the thermosetting resin, the thermosetting agent, and the inorganic filler.

### (Inorganic Filler)

The inorganic filler in the thermosetting composition is used to adjust the durometer A hardness, the storage elastic modulus at the frequency of 200 Hz, and the storage elastic modulus after curing, of the black transfer layer, and silica, talc, titanium oxide, calcium carbonate, magnesium oxide, a silane coupling agent, a diluent monomer, a bulking agent, a softener, a colorant, a flame retardant, a thixotropic agent, or the like, other than the black pigment, can be used. The inorganic filler may be used alone or in combination of two or more.

The content of the inorganic filler is preferably 1 part by mass or more and 20 parts by mass or less, more preferably 5 parts by mass or more and 15 parts by mass or less, and particularly preferably 8 parts by mass or more and 12 parts by mass or less, relative to 100 parts by mass of the total of the rubber component, the film-forming resin, the thermosetting resin, the thermosetting agent, and the inorganic filler. In particular, when the content of the rubber component is 2 parts by mass or more and 10 parts by mass or less relative to 100 parts by mass of the total of the rubber component, the film-forming resin, the thermosetting resin, the thermosetting agent, and the inorganic filler, and the content of the inorganic filler is set to 8 parts by mass or more and 12 parts by mass or less, the desired durometer A hardness, storage elastic modulus at the frequency of 200 Hz, and storage elastic modulus after curing can be easily adjusted.

### (Conductive Particle)

The black transfer layer may further contain conductive particles. When the black transfer layer contains the conductive particles, the black transfer layer and the black matrix derived therefrom can function as a conductive layer or an anisotropic conductive layer. As the conductive particles, those used in known conductive films or anisotropic conductive films can be appropriately selected and used. Examples thereof include metal particles of nickel, copper, silver, gold, palladium, solder and the like, and metal-coated resin particles obtained by coating the surface of resin particles such as polyamide and polybenzoguanamine with a metal such as nickel and gold. Thus, even when a connection portion such as a solder bump is not provided in the chip component, conduction is possible. For example, in the first aspect of the present invention, it is possible to electrically connect the light-emitting elements to the wiring substrate at the same time when forming the black matrix.

The average particle diameter of the conductive particles is usually 1 μm or more and 50 μm or less, and is preferably 1 μm or more and 20 μm or less, more preferably 1.5 μm or more and 15 μm or less from the viewpoint of the capturing efficiency of the conductive particles in the connection structure. The average particle diameter may be 1.5 μm or more and less than 2.5 μm in order for the conductive particles to be applied to a micro-sized electrode. The average particle diameter of conductive particles can be measured by an image-based particle size distribution meter (e.g., FPIA-3000, manufactured by Malvern-Panalytical Ltd.). Furthermore, the particle surface density of the conductive particles in the black transfer layer can be determined according to the electrode area of the chip component or the like. For example, the lower limit of the particle surface density can be preferably 500 particles/mm² or more, and the upper limit is preferably 200,000 particles/mm² or less, more preferably 150,000 particles/mm² or less, and particularly preferably 120,000 particles/mm² or less. The size and number density of the conductive particles can be adjusted so as not to impair the advantageous effects of the black pigment.

In addition, it is preferable that the conductive particles be individually and independently disposed in the film surface view in the black transfer layer. In this case, it is preferable that 95% or more of conductive particles should be independent on a number basis. Furthermore, the conductive particles are preferably disposed not only individually but also regularly. In particular, an arrangement in which the particle arrangements in the respective directions orthogonal to each other in the film surface view are periodically repeated is preferred. For example, a lattice arrangement such as a hexagonal lattice, a rectangular lattice, an orthorhombic lattice, a square lattice, or other rectangular lattice can be mentioned. In addition, rows of particles in which the conductive particles are linearly arranged at predetermined intervals may be arranged in parallel at predetermined intervals. As described above, by regularly arranging the conductive particles in the film surface view, it is possible to make the conductive particle surface density uniform. This can further improve the transfer rate of the chip component by irradiation of laser light.

### (Ultraviolet Absorbing Resin)

The thermosetting composition constituting the black transfer layer may contain an ultraviolet absorbing resin (a resin having a benzene skeleton or a naphthalene skeleton such as an aromatic epoxy resin, a phenoxy resin, an aromatic polyimide resin, or an aromatic polysulfone resin) for improving the laser lift-off properties. These components may overlap with the rubber component, the film-forming resin, or the like.

### <Fourth Aspect of Present Invention>

The fourth aspect of the present invention is a preferable aspect of the black transfer film used in the producing methods of the first to third aspects described above. Specifically, the black transfer film for forming the black matrix using the laser lift-off method includes a light-transmitting base material such as a polyethylene terephthalate film and a black transfer layer formed on one side of the light-transmitting base material. As described above, the black transfer layer includes a black pigment and a thermosetting composition. The visible light transmittance according to JIS K 7375 of the black transfer layer is less than 20%, preferably less than 10%, and the tack force according to JIS Z 0237 of the black transfer layer is 0.1 MPa or more in order to ensure transferability of individual pieces. Furthermore, the cushioning properties of the black transfer layer are as already described. Note that the black transfer layer is preferably provided on the light-transmitting base material in the form of individual pieces corresponding to the black matrix to be formed. Furthermore, the black transfer layer preferably includes conductive particles to impart conductivity or anisotropic conductivity to the black transfer film.

### EXAMPLES

The present invention will be described in more detail below with examples.

### <Production of Black Transfer Film>

Transfer layer forming compositions (i), (ii), (iii), (iv), and (v) in Table 1 were each mixed, and the resulting mixtures were applied to light-transmitting base materials and subjected to a drying process at 60° C. for 3 minutes to obtain black transfer films (i), (ii), (iii), and (iv) of the present invention each including a black transfer layer with a thickness of 6 μm. Note that, the transfer layer forming composition (v) was used to obtain a white transfer film (v) including a white transfer layer.

Next, conductive particles (Micropearl AU, Sekisui Chemical Co., Ltd.) were regularly arranged to a particle density of 58,000 particles/mm² using the conductive particle regular arrangement process described in paragraphs 0111 and 0112, and FIG. 1A of Japanese Patent No. 6187665, and then transferred to the black transfer films or the white transfer film, thereby imparting anisotropic conductivity to the black transfer films (i), (ii), and (iii) and the white transfer film (v). The black transfer film (iv) is an example in which no conductive particles are used.

TABLE 1
Parts by mass

| | | Transfer layer forming | | | | |
|---|---|---|---|---|---|---|
| | | composition | | | | |
| Components | Providers | (i) | (ii) | (iii) | (iv) | (v) |
| Phenoxy resin | PKHH, Tomoe | 45 | 45 | 45 | 45 | 35 |
| | Engineering Co., Ltd. | | | | | |
| Liquid epoxy | YL980, Mitsubishi | 40 | 40 | 25 | 45 | 35 |
| resin | Chemical Corp. | | | | | |
| Fumed silica | RY200, Nippon Aerosil | 5 | 5 | 5 | 5 | 5 |
| | Co., Ltd. | | | | | |
| Carbon black | MA600, Mitsubishi | 5 | | 5 | 5 | |
| | Chemical Corp. | | | | | |
| Titanium black | Tilack D TM-F, Ako | | 20 | | | |
| | Kasei Co., Ltd. | | | | | |
| Cationic | San Aid SI60L, Sanshin | 10 | 10 | 10 | 10 | 10 |
| polymerization | Chemical Industry Co., | | | | | |
| initiator | Ltd. | | | | | |

The obtained black transfer films and white transfer film were subjected to the following evaluation tests from the viewpoint of producing the black matrix by changing material compositions and film temporary fixing methods. The evaluation results are shown in Table 2. Specifically, Examples 1, 2 and 3 are examples in which the black transfer films (i), (ii), and (iii) were used to form black matrices by transferring the black transfer layers as individual pieces using the laser lift-off method. Comparative example 1 is an example in which the white transfer film (v) was used to form a white matrix by transferring the white transfer layer as individual pieces using the laser lift-off method. Comparative examples 2 and 3 are examples in which the black transfer films (i) and (iv) were used to transfer the black transfer layers as a full-surface-applied layer using the laser lift-off method.

### <Film Tackiness Evaluation Test>

The film tackiness of the black transfer films of Examples 1 to 3 and Comparative example 1 was measured using a tack tester (TAC-II, Rhesca Co., Ltd.). The tack test was performed under the following conditions: a probe diameter Φ of 5.1 mm, an initial load of 40 gf/cm², a pressure time of 1 sec, and a test speed of 2 mm/sec.

### (Film Tackiness Evaluation)

### Score Criteria

A: 0.4 Mpa or more
B: 0.2 Mpa or more and less than 0.4 Mpa
C: 0.1 Mpa or more and less than 0.2 Mpa
D (NG): less than 0.1 Mpa

### <Light Blocking Property Evaluation Test>

The black transfer films in Examples 1 to 3 and Comparative examples 2 and 3, and the white transfer film in Comparative example 1 were each attached to a glass substrate with a size of 5×5 cm and a thickness of 0.5 mm, and the light transmittance was measured using a transmittance measuring device (USPM-CS01, Olympus Corp.) to evaluate the light blocking properties of the films. The visible light transmittance was calculated from the average transmittance of 400 to 700 nm.

### (Light Blocking Property Evaluation)

### Score Criteria

A: Less than 10%
B: 10% or more and less than 15%
C: 15% or more and less than 20%
D (NG): 20% or more

### <Individual Piece Landing Property Evaluation Test for Individual Piece Film>

A thousand individual pieces, each measuring 30×40 μm, of each of the black transfer layers of the black transfer films in Examples 1 to 3 and a thousand individual pieces, each measuring 30×40 μm, of the white transfer layer of the white transfer film in Comparative example 1 were prepared and each transferred to plain glasses 100 μm away using a laser lift-off device (MT-30C200) under the following conditions to calculate landing rates, and the landing property of the individual pieces of the films was evaluated.
Laser: excimer laser with oscillation wavelength of 248 nm
Laser light pulse energy: 600 J
Fluence: 150 J/cm²
Pulse duration (irradiation time): 30,000 picoseconds
Pulse frequency: 0.01 kHz
Number of irradiation pulses: 1 pulse for each small piece of transfer layer
Pulse energy of laser light that is applied and imaged on interface between black transfer layer and light-transmitting base material: 0.001 to 2 J
Fluence: 0.001 to 2 J/cm²
Pulse duration (irradiation time): 0.01 to 1×10⁹ picoseconds
Pulse frequency: 0.1 to 10,000 Hz
Number of irradiation pulses: 1 to 30,000,000 pulses
Mask used: a pattern was used in which an arrangement of windows of a predetermined size is formed at a predetermined pitch so that the projection of laser light on the interface between the black transfer layer and the plain glass was formed in an arrangement of 30 μm long×40 μm wide with a pitch of 120 μm long and 160 μm wide.

### (Individual Piece Landing Property Evaluation for Individual Piece Film)

### Score Criteria

A: 99.9% or more
B: 99.0% or more and less than 99.9%
C: 90.0% or more and less than 99.0%
D (NG): Less than 90.0%

### <Black Area Occupancy Ratio (%)>

For the full-surface-applied films in Comparative examples 2 and 3, each sample was prepared in which the film was attached to the entire surface of the glass substrate. For the individual piece films in Examples 1 to 3 and Comparative Example 1, each sample was prepared in which one piece was landed on the glass substrate at a pitch interval of 400 μm long and 300 μm wide. The individual piece film with the individual pieces landed on the glass substrate or the surface-applied film was examined using a metallurgical microscope. Observation was performed in a measurement area with a range of 1 mm×1 mm to examine black areas.

### <Conduction Resistance>

LED chips for evaluation were placed on the applied object to which the black transfer film was temporarily fixed, and pressure-bonding was performed at 200° C. and 10 MPa for 30 seconds to obtain a mounted body. Two pairs of 10×10 μm electrodes were provided to the LED chips for evaluation, and the conduction resistance was measured through a conduction wiring on the substrate side. A total of 30 sites were measured to determine the average conduction resistance.

### (Conduction Resistance Evaluation)

### Score Criteria

A: 50Ω or less
B: greater than 50Ω and 100Ω or less
C: greater than 100Ω and 200Ω or less
D (NG): greater than 200Ω

TABLE 2

| | Example | | | Comparative Example | | |
|---|---|---|---|---|---|---|
| | 1 | 2 | 3 | 1 | 2 | 3 |
| Temporary fixing | Individual | Individual | Individual | Individual | Full | Full |
| method | piece | piece | piece | piece | surface | surface |
| | transfer | transfer | transfer | transfer | application | application |
| Material | (i) | (ii) | (iii) | (v) | (i) | (iv) |
| composition | | | | | | |
| Film tackiness | A | A | C | A | — | — |
| Light blocking | A | A | A | D | A | A |
| properties | | | | | | |
| Individual piece | A | A | C | A | — | — |
| landing | | | | | | |
| properties | | | | | | |
| Black area | 10 | 10 | 10 | (10) | 100 | 100 |
| occupancy ratio | | | | | | |
| (%) | | | | | | |
| Conduction | A | A | A | A | A | D |
| resistance | | | | | | |

### <Discussion of Results>

The film tackiness affects the landing properties of the individual pieces of the film. However, even in Example 3, which had the lowest tackiness, the black transfer film (iii) used did not cause any practical problems. Further, the black transfer films including carbon black or titanium black, which were used in Examples 1 to 3 and Comparative examples 2 and 3, exhibited favorable light blocking properties.

Furthermore, in Examples 1 to 3, the black anisotropic conductive transfer films were transferred as individual pieces, making it possible to obtain the mounted bodies that achieved both conduction resistance and light blocking properties as characteristics of the black matrix. Moreover, the black matrix can be formed selectively, only in necessary sites. This makes it possible to obtain advantages such as enabling applications in transparent displays and improving the alignment of LED chips.

Note that, when the black transfer film (iv) that does not include the conductive particles and does not exhibit the anisotropic conductive properties was used to transfer individual pieces in the same manner as in Example 1, the conduction resistance tended to be high. However, the results for other evaluation items were almost the same as those in Example 1.

On the other hand, in Comparative example 1, due to the use of the white transfer film, it was not suitable for producing the black matrix in the first place. In Comparative examples 2 and 3, since the black transfer film was applied to the entire surface, it was necessary to further perform patterning of the black transfer layer in order to create the black matrix.

In the above-mentioned Examples 1 to 3, the black transfer films that included conductive particles were used. However, if the specifications of the bump conditions of the micro LEDs were changed such that sufficient conductivity can be obtained without the use of conductive particles, it is expected that the black transfer film that does not include the conductive particles can be used in practice as long as the black transfer film satisfies the evaluations other than conductivity performance.

### INDUSTRIAL APPLICABILITY

To prevent color mixing of the micro LEDs, a black matrix needs to be formed between the LEDs. However, unlike LCDs or OLED displays, the micro LED displays can not provide the black matrix to the color filter layer because of using no color filter. In the present invention, the black matrix can be more easily formed using the laser lift-off technique. The black transfer film is a thermosetting film and can also be used as a conductive film for LEDs. This technology makes it possible to shorten the process and reduce costs for connecting the LEDs and forming the black matrix.

### REFERENCE SIGNS LIST

1, 21, 31 wiring
2, 22, 32 wiring substrate
3, 23, 33 light-transmitting base material
4, 24, 34 black transfer layer
5, 25, 35 black transfer film
6, 26, 36 light-emitting element
6a, 26a, 36a electrode of light-emitting element
7 bonding tool
8, 28, 38 black matrix
29, 39 conductive adhesive layer
L laser light

1. A producing method for a light-emitting device including a black matrix in at least a part of peripheries of light-emitting elements disposed on a wiring substrate, the producing method comprising a step a, a step b, and a step c as follows:
(Step a)
allowing a black transfer film with a black transfer layer that has been formed on one side of a light-transmitting base material to face, from the black transfer layer side, the wiring substrate before the light-emitting elements are disposed thereon;
(Step b)
applying laser light to the black transfer film from the light-transmitting base material side thereof, thereby transferring individual pieces of the black transfer layer to positions on the wiring substrate where the light-emitting elements are to be disposed; and
(Step c)
disposing and mounting the light-emitting elements on the individual pieces of the black transfer layer that have been transferred to the wiring substrate, thereby deforming the black transfer layer to form a black matrix in at least the part of the peripheries of the light-emitting elements and connecting the light-emitting elements to the wiring substrate.

2. A producing method for a light-emitting device including a black matrix in at least a part of peripheries of light-emitting elements disposed on a wiring substrate, the producing method comprising a step A1a and a step A1b as follows:
(Step A1a)
allowing a black transfer film with a black transfer layer that has been formed on one side of a light-transmitting base material to face, from the black transfer layer side, the wiring substrate on which the light-emitting elements have been disposed; and
(Step A1b)
applying laser light to the black transfer film from the light-transmitting base material side thereof, thereby transferring individual pieces of the black transfer layer to at least the part of the peripheries of the light-emitting elements on the wiring substrate to form a black matrix.

3. A producing method for a light emitting device including a black matrix in at least a part of peripheries of light-emitting elements disposed on a wiring substrate, the producing method comprising a step A2a, a step A2b, and a step B as follows:
(Step A2a)
allowing a black transfer film with a black transfer layer that has been formed on one side of a light-transmitting base material to face, from the black transfer layer side, the wiring substrate before the light-emitting elements are disposed thereon;
(Step A2b)
applying laser light to the black transfer film from the light-transmitting base material side thereof, thereby transferring individual pieces of the black transfer layer to at least a part of peripheries of positions of the wiring substrate where the light-emitting elements are to be disposed to form a black matrix; and
(Step B)
disposing the light-emitting elements between the black matrices that have been transferred to the wiring substrate.

4. The producing method according to claim 1, wherein the light-emitting elements are micro LEDs.

5. The producing method according to claim 1, wherein the black transfer film is a film in which the black transfer layer is provided as a full-surface-applied layer on one side of the light-transmitting base material.

6. The producing method according to claim 1, wherein the black transfer film is a film in which individual pieces of the black transfer layer are provided on the light-transmitting base material so as to correspond to at least a part of peripheries of positions of the wiring substrate where the light-emitting elements are to be disposed.

7. The producing method according to claim 1, wherein the black transfer layer contains conductive particles to exhibit conductivity.

8. The producing method according to claim 7, wherein the black transfer layer exhibits anisotropic conductivity.

9. A black transfer film for forming a black matrix by using a laser lift-off method, the black transfer film comprising:
a light-transmitting base material and a black transfer layer formed on one side of the light-transmitting base material,
the black transfer layer including a black pigment and a thermosetting composition, the black transfer layer having a visible light transmittance according to JIS K 7375 of less than 20% and a tack force according to JIS Z 0237 of 0.1 MPa or more.

10. The black transfer film according to claim 9, wherein a durometer A hardness of the black transfer layer is 20 or more and 40 or less.

11. The black transfer film according to claim 9, wherein a storage elastic modulus of the black transfer layer as determined by dynamic viscoelasticity testing (conditions: measuring at a temperature of 30° C. and a frequency of 200 Hz, using a flat punch with a diameter of 100 μm, setting a target push-in depth to 1 μm, and sweeping in a frequency range of from 1 to 200 Hz) is 60 MPa or less.

12. The black transfer film according to claim 9, wherein the black transfer layer is provided on the light-transmitting base material in a form of individual pieces corresponding to the black matrix to be formed.

13. The black transfer film according to claim 9, wherein the black transfer layer contains conductive particles to exhibit conductivity.

14. The black transfer film according to claim 13, wherein the black transfer layer exhibits anisotropic conductivity.
